(19) United States
(12) Patent Application Publication
(10) Pub. No.: US 2025/0119177 A1
(43) Pub. Date: Apr. 10, 2025

(54) MEASUREMENT SYSTEM AND METHOD FOR CHARACTERIZING A MULTI-CORE CABLE

(71) Applicant: Turck Holding GmbH, Halver (DE)

(72) Inventors: Thomas Hartisch, Grünhain-Beierfeld (DE); Jürgen Daniel Wohlrab, Thum (DE)

(73) Assignee: Turck Holding GmbH, Halver (DE)

(21) Appl. No.: 18/895,665

(22) Filed: Sep. 25, 2024

(30) Foreign Application Priority Data
Oct. 6, 2023 (DE) 102023127325.6

(51) Int. Cl. H04B 3/46; G01R 31/58

(52) U.S. Cl. CPC H04B 3/46; G01R 31/58

(57) ABSTRACT

A measurement system having at least two data capture units and a central processing unit, for characterizing a multi-core cable. The two data capture units are each provided for being contact-connected to the cable at an end-side terminal and each capture an electrical measurement variable at there, at least in an active state of the cable (2). The data capture units each have a communication module for establishing a wireless peripheral connection between the data capture units to transfer the respectively captured measurement variable from one of the data capture units to the respective other data capture unit. The communication module of at least one of the data capture units and a communication module of the central processing unit establish a single wireless central connection therebetween in order to transfer at least one of the captured measurement variables to the central processing unit.

### CROSS-REFERENCE TO RELATED APPLICATIONS

This application claims priority from German Patent Application No. 10 2023 127 325.6, filed Oct. 6, 2023, which is incorporated herein by reference as if fully set forth.

### TECHNICAL FIELD

The present invention relates to a measurement system and a method for characterizing a multi-core cable.

### BACKGROUND

Multi-core cables can be used in various applications to transmit data and signals or, for example, to supply energy. The cores of such a cable are each one or more electrical conductors, each of which is typically surrounded by an insulation layer. This makes it possible to arrange the cores in close contact with each other in the core of the cable and to protect them from external influences by means of a common sheath layer. To connect the multi-core cable to one or more electrical apparatuses, the cable is typically provided with terminals at the ends.

When using the multi-core cable, it is desirable to ensure a permanently reliable transferability of data and signals as well as a reliable energy supply. However, this is complicated by the fact that the components of said cable may have different qualities in terms of their electrical properties, depending on the origin and condition of the materials used. Similarly, the electrical properties of the cable can deteriorate due to aging and can thus hinder reliable transmission of data and signals as well as energy supply. Especially due to environmental influences or mechanical stress, for example, the reliability of the cable can deteriorate when transmitting data and signals or the energy supply.

### SUMMARY

There is therefore a need to be able to ensure that the nature of the multi-core cable meets the existing requirements. Accordingly, it is an object of the invention to propose means which make it possible to check the nature of a multi-core cable in a simple and reliable manner.

The object is achieved by a measurement system for characterizing a multi-core cable having one or more of the features described herein and a method for characterizing a multi-core cable having one or more of the features described herein. Advantageous developments are defined below and in the claims.

The measurement system according to the invention serves to characterize a multi-core cable and comprises at least two data capture units and a central processing unit. The two data capture units are each provided for being contact-connected to the cable at an end-side terminal and are designed to each capture at least one electrical measurement variable at the end-side terminals at least in an active state of the cable. The data capture units and the central processing unit each comprise a communication module. The communication modules of the data capture units are provided for establishing a wireless peripheral connection between the data capture units in order to transfer the respectively captured measurement variable from one of the data capture units to the respective other data capture unit. The communication module of at least one of the data capture units and the communication module of the central processing unit are provided for establishing a single wireless central connection between the respective data capture unit and the central processing unit in order to transfer at least one of the captured measurement variables and/or a variable dependent thereon to the central processing unit.

The measurement system according to the invention makes it possible in a simple way to determine the electrical properties of a multi-core cable already during its manufacture in order to be able to determine whether these meet the desired requirements. It is also possible to perform such a characterization during the operation of the cable.

The data capture units may each comprise an electrical circuit comprising at least one sensor and an electrical control unit, for example a microcontroller. The sensor can be electrically contact-connected here to at least some of the cores of the multi-core cables and is used to capture an electrical measurement variable, preferably a plurality of electrical measurement variables. The control unit can be used to supply the sensor with electrical energy and to control it to capture the electrical measurement variable.

Within the scope of the invention, the data capture units are each individually designed to capture the at least one electrical measurement variable. In other words, one of the data capture units may be a first data capture unit and the respective other of the data capture units may be a second data capture unit. The first data capture unit is designed here to capture at least one electrical measurement variable, preferably a plurality of electrical measurement variables, at a first terminal and the second data capture unit is designed to capture the electrical measurement variable, preferably the plurality of electrical measurement variables, at a second terminal. In particular, the electrical measurement variables, which are respectively captured at the first and second terminals, are identical in nature. However, the measurement variables can differ from each other in terms of absolute value or by another characteristic, with the result that it is possible to draw a conclusion about the state of the cable or one of its cores by comparing the measurement variables.

The invention is basically not limited to the electrical measurement variable that can be determined by means of the data capture units. The active state of the cable can be regarded as an operating state in which current flows through at least one of the cores or a potential is present between two of the cores. The active state can be caused, for example, by operating the cable by connecting it between an electrical energy source and a load. It is also conceivable for at least one of the data capture units to be designed to bring about the active state, for example by applying a test voltage between two of the cores.

In a simple exemplary embodiment, the data capture units are each designed to be electrically contact-connected to a supply core and/or a signal core and a reference potential core of the cable, and to measure a current intensity in the supply core and/or the signal core and/or the reference potential core and/or a voltage between the supply core and/or the signal core and the reference potential core. The ohmic resistance of at least one of the cores can be inferred, for example, by comparing the respectively measured variables at the end-side terminals of the cable.

The central processing unit can be regarded as a computing unit which is used to evaluate the captured electrical measurement variables determined by at least one of the data capture units.

As explained above, it is essential for the invention that the data capture units and the central processing unit each comprise a communication module. These may be radio modules which make it possible to establish the two different types of wireless connections referred to as peripheral connection and central connection within the scope of the invention. The peripheral connection can be considered a wireless connection between the data capture units, while the central connection can be considered a wireless connection between only one of the data capture units and the central processing unit.

The peripheral connection can be considered a so-called master-slave connection. The communication modules of the data capture units can each operate in two modes, i.e. in a dual topology mode. In particular, the communication modules of the data capture units are provided for multi-central connections, which means that a data capture unit can simultaneously assume a central and a peripheral role and can also be connected to a plurality of central processing units simultaneously. The connection limit of a data capture unit for the total number of possible connections is in particular independent here of the role in which the data capture unit can act.

In conventional connection configurations of wireless networks that comprise a plurality of data capture units and a central processing unit, it is common for each of the data capture units to be identified as being ready for a connection and for the central processing unit to then connect to these data capture units. However, the total number of data capture units that can be connected to the central processing unit is limited by the available number of connection places of the central processing unit. According to the invention, provision is therefore made for the data capture units to establish a peripheral connection to each other and for the central processing unit to establish only a single central connection to only one of the data capture units of the measurement system. This halves the number of connection places required at the central processing unit compared to conventional connection configurations. Conversely, it is thus possible according to the invention to operate twice the number of peripheral data capture units with only one central processing unit than would normally be provided.

It is therefore within the scope of the invention that one of the data capture units captures an electrical measurement variable, preferably a plurality of electrical measurement variables, and transfers this via the peripheral connection to the respective other data capture unit or vice versa. At the same time, only one of the data capture units is connected to the central processing unit by means of the central connection and transfers at least one or both of the captured measurement variables and/or a variable dependent thereon to said central processing unit. It is therefore in particular within the scope of the invention that the measurement variables are pre-processed in at least one of the data capture units and only then transferred to the central processing unit.

In principle, the invention is not limited to which of the two data capture units is designed to form the central connection to the central processing unit. In other words, both data capture units may be able to enter into a central connection with the central processing unit. It is only relevant that only one of the two data capture units is connected to the central processing unit at one time, with the result that there is only a single central connection in the measurement system. Preferably, the measurement system is designed in such a way that the central processing unit establishes the central connection to one of the data capture units and not the other way around.

In an advantageous development, the communication modules of the data capture units and of the central processing unit are each Bluetooth modules, in particular Bluetooth low-energy modules.

Within the scope of the development described above, a Bluetooth module is a hardware component that enables wireless communication to be established by means of the “Bluetooth” wireless communication standard in order to transmit data. If the data capture units comprise a sensor and an electrical control unit, the Bluetooth modules can be supplied with electrical energy and controlled by means of the respective electrical control unit.

As described above, the Bluetooth modules can be Bluetooth low-energy modules that communicate with each other using a Bluetooth low-energy protocol. This is a variant of the Bluetooth protocol that allows the energy requirement of the data capture units, and in particular their communication modules, to be minimized. Other advantages of the Bluetooth low-energy modules are small data packets and a fast connection establishment between the communication modules.

In particular, the data capture units may each have their own electrical energy store, for example an electric battery or an electric rechargeable battery. Using Bluetooth low-energy modules as communication modules makes it possible to reduce their energy requirement as explained above, thus allowing an extended runtime.

In an advantageous development, the data capture units are each integrated in one of the end-side terminals and the terminals are provided for being connected to at least two, preferably at least three, in particular at least four, cores of the cable. In particular, the measurement system also comprises the end-side terminals.

An advantage of the development described above is a high degree of functional integration. This is due to the fact that both the electrical contact-connection of the multi-core cables and the capture of the electrical measurement variables at the terminals and the transmission of the electrical measurement variables can each be realized by a single technical component. In particular, the assembly effort for manufacturing a multi-core cable can be reduced, since the electrical contact-connection of the terminals and the arrangement of the data capture units can be carried out in just one assembly step. In addition, the state of the cable can also be monitored temporarily or even permanently after delivery and during operation.

In an advantageous development, one of the end-side terminals comprises a plug and the respective other end-side terminal comprises a socket.

The plug can be regarded as a male connection element for the multi-core cable, which has outward facing contact elements, in particular contact pins. The socket can be regarded as a female connection element for the multi-core cable, which has a housing with one or more contact surfaces or openings and is used to enter into an electrical connection with the contact elements of a plug. It is within the scope of the advantageous development that the plug and the socket correspond to each other. Alternatively, the plug and socket may not correspond to each other in each case, depending on which electrical devices they are intended to connect to each other.

In an advantageous development, the data capture units are each designed to be electrically contact-connected to a supply core and/or a signal core and a reference potential core of the cable, and to measure a current intensity in the supply core and/or the signal core and/or the reference potential core and/or a voltage between the supply core and the reference potential core and/or between the signal core and the reference potential core.

The supply and reference potential cores can be used for electrical energy and power transmission between an electrical energy source and a load. The electrical properties of the cable can be inferred by means of the data capture units by measuring the current intensity and/or the voltage. In particular, it can be determined whether and to what extent the suitability of the cable for the transmission of electrical energy and power is impaired. The signal core can be used to transmit one or more signals, wherein the signals can be present, for example, as a voltage signal or as a current signal.

In an advantageous development, the data capture units are each designed to be electrically contact-connected to at least one signal core and to capture a signal characteristic in the signal core, in particular a bus signal.

The signal core is used to transmit one or more signals between the end-side terminals of the cable. The signal can be present here as a voltage signal and/or a current signal. The data capture units may be configured to capture an amplitude, a frequency, a phase shift, a rise time, a fall time, signal distortion, and/or signal noise. In particular, the data capture units may be designed to send and receive a reference signal, on the basis of which the signal characteristic is assessed.

In an advantageous development, the data capture units and/or the central processing unit each have a memory module on which at least one identification code, in particular a media access control (MAC) ID is stored, via which the data capture units are assigned to each other for the wireless peripheral connection and/or via which at least one of the data capture units is assigned to the central processing unit for the wireless central connection.

Within the scope of the advantageous development, the identification code is used to ensure a clear assignment between the data capture units or between the central processing unit and one of the data capture units. This is particularly advantageous when more than just the two data capture units of the measurement system are in sufficient proximity to each other or to the central processing unit, with the result that in principle a plurality of wireless data connections can be established. This may be the case during the manufacture of a multi-core cable, in particular during its assembly with a measurement system according to the invention, or in later operation.

In an advantageous development, at least one of the data capture units has an evaluation module which is configured to process the measurement variables captured at the two end-side terminals and to transfer a variable dependent thereon to the central processing unit.

In a simple exemplary embodiment, the evaluation module may be an electrical controller, in particular a microcontroller, which can preprocess the measured measurement variables. Furthermore, the evaluation module may be the electrical control unit which is also used to control the respective sensor. The processing of the measurement variables can be carried out in different ways and can comprise, for example, filtering, formation of differences, quotients or averages, a transformation, in particular a Fourier transform, data compression, measured value smoothing or interpolation, or signal amplification.

Filtering can be used to reduce unwanted noise or isolate specific frequency ranges. Different types of digital filters are available, such as low-pass, high-pass, bandpass and notch filters. Characteristic variables that can be easily interpreted can be calculated from the measurement variables by forming averages, quotients or differences. The Fourier transform, in particular the Fast Fourier Transform (FFT), allows the electrical control unit to transform signals from the time domain to the frequency domain. This allows specific frequency components to be identified and spectral analysis to be performed. In applications with limited memory, data compression can be used to reduce an amount of data present and to store and transmit information more efficiently.

In particular, the dependent variable comprises a temporal profile of at least one of the measurement variables. In particular, the temporal profile may comprise a plurality of discrete measurement points, each of which is assigned a measurement time. It is also possible for the evaluation module to be designed to convert the discrete temporal profile into an at least partially continuous profile by means of interpolation or a comparable method.

Based on the temporal profile of the measurement variable, it is possible to determine a signal propagation time by capturing a signal using the data capture units and comparing the measurement times with each other. It is also possible to determine or at least estimate a cable length from this.

A cable impedance can also be determined based on the temporal profile of the measurement variable. Cable impedance is an important parameter that indicates the effect on signal quality due to the nature of the cable. Cable impedance can be considered an AC resistance and can be defined by the ratio of the temporal profiles between voltage and current. In particular, the data capture units are preferably each designed to capture a current intensity and/or a voltage such that the cable impedance can be determined from their temporal profiles.

In an advantageous development, the measurement system comprises at least three data capture units, each provided for being contact-connected at the end-side terminals of a multi-core Y-cable, and each designed to capture an electrical measurement variable, preferably a plurality of electrical measurement variables, at one of the end-side terminals at least in an active state of the Y-cable. The data capture units each comprise a communication module. The communication modules of the data capture units are each provided for establishing two wireless peripheral connections between two of the three data capture units in each case. The communication module of at least one of the three data capture units is also designed to establish a single wireless central connection to the communication module of the central processing unit.

It is an advantage of the advantageous development described above that a plurality of peripheral connections can be formed between three data capture units in order to characterize a multi-core Y-cable. A multi-core Y-cable is a type of electrical cable that comprises a single trunk section that is divided into two branch sections. This type of cable is often used in power supply or distribution systems to transmit information or electrical energy from a central point to a plurality of loads or devices, or vice versa.

It is an advantage that, even for the characterization of a Y-cable, only a central connection between one of the three data capture units and the central processing unit is required, wherein it is basically irrelevant to which of the three data capture units the central processing unit establishes the central connection. In addition, the advantageous development is not limited to the data capture units between which the two peripheral connections are established.

Thus, in a first connection configuration, the measurement system can have one of three data capture units, which is connected to the central processing unit via a central connection and is simultaneously connected to the two other data capture units via two peripheral connections.

In a second connection configuration, the measurement system also has a first of three data capture units, which is connected to the central processing unit via a central connection and is simultaneously connected to a second of the three data capture units via a first peripheral connection. The second data capture unit is in turn connected to a third data capture unit via a second peripheral connection.

It is within the scope of the advantageous development that the connection configuration is variable, at least between the first and second connection configurations described above.

As explained above, the object is also achieved by means of a method for characterizing a multi-core cable. The method according to the invention comprises the following method steps of:
A) providing a measurement system according to the invention or an advantageous development thereof, as well as a multi-core cable;
B) electrically contact-connecting the at least two data capture units to the cable via an end-side terminal in each case;
C) applying an electrical voltage to the cable;
D) establishing a wireless peripheral connection between the data capture units of the measurement system;
E) establishing a single wireless central connection between the central processing unit and only one of the data capture units;
F) capturing at least two electrical measurement variables at the terminals by means of the data capture units;
G) transferring at least one of the captured measurement variables between the data capture units via the peripheral connection;
H) transmitting at least one of the captured measurement variables and/or a variable dependent thereon from one of the data capture units to the central processing unit via the central connection.

The method according to the invention is provided for being carried out by means of a measurement system according to the invention or an advantageous development thereof. In this respect, the statements apply accordingly with regard to the advantages that can be achieved with the measurement system. In particular, the measurement variable transmitted in method step H) can be pre-processed or a variable derived therefrom can be transferred.

In an advantageous development, in method step D), advertising takes place between the communication modules of the data capture units.

Within the scope of the advantageous development, “advertising” can be understood as meaning a process in which the communication modules send information about themselves to other communication modules in their environment. This process is also known as “beaconing”. The aim of advertising is to communicate their presence, available services or data packets to other devices without a direct connection having to be established. If the communication modules are designed as Bluetooth modules or in particular Bluetooth low-energy modules, advertising is an important part of the corresponding Bluetooth protocol, which allows Bluetooth devices to remain in a power-saving state and only briefly communicate their presence and data to other devices.

Advertising can be used to transmit information from the data capture unit, such as the device name or user-defined data. This information can be captured by at least one other data capture unit and used to establish a connection to the advertising device. Optionally, further data could also be transferred by means of advertising and could contain additional information or details, for example, that are sent in response to a specific request. It is a possible way for the advertising device to only provide more information as needed without increasing the length of an initial advertising packet.

In an advantageous development, according to method step D), one of the data capture units provides the respective other data capture unit with an advertising time window, wherein, if a connection is lost between one of the data capture units and the central processing unit and if the advertising time window is exceeded, the central processing unit establishes a wireless central connection to the respective other data capture unit. In this way, it is possible to ensure that only one central connection is established at a time.

In particular, the two data capture units can exchange a token until the central processing unit has established a wireless connection to one of the data capture units. The token can be regarded here as a character string or a comparable identification feature, which can be stored only by that data capture unit which is connected to the central processing unit via the central connection or to which such a central connection is intended to be established. It is also within the scope of the development that the token is always stored only by that data capture unit which is not intended to establish the central connection.

In an advantageous development, in method step E), advertising takes place between at least one of the communication modules of the data capture units and the communication module of the central processing unit. In particular, the advertising between at least one of the communication modules of the data capture units and the communication module of the central processing unit makes it possible to determine which of the data capture units is associated with a better connection quality even before the central connection is established.

In an advantageous development, by means of the central processing unit, a Received Signal Strength Indicator (RSSI) value is assigned to at least one of the two data capture units and stored in method step E).

The RSSI value can be regarded as a receive signal strength. It is a measured value that indicates the strength of a received signal from a wireless data connection, in particular by means of Bluetooth. The RSSI value is usually expressed in decibels (dBm) and indicates the power of the received signal relative to the reference power (1 milliwatt). The higher the RSSI value, the stronger the received signal. A low RSSI value, on the other hand, indicates a weak signal strength.

In an advantageous development, by means of the central processing unit, a Received Signal Strength Indicator (RSSI) value is respectively assigned to the two data capture units and stored, and the central connection is established between the central processing unit and that data capture unit to which the higher Received Signal Strength Indicator (RSSI) value is assigned. This ensures that the wireless central connection is established to that data capture unit which is associated with the better signal quality, which typically results in a more reliable and more powerful connection. This can be particularly useful for improving the quality of wireless communication in environments with weak signals or interference.

### BRIEF DESCRIPTION OF THE DRAWINGS

The advantages of the invention are explained below with reference to exemplary embodiments and the figures, in which:

FIG. 1 shows a multi-core cable with a measurement system;

FIG. 2 shows a connection configuration of the measurement system;

FIG. 3 shows an exemplary pin assignment plan of two data capture units of the measurement system with the cores of the multi-core cable; and

FIG. 4 shows a multi-core Y-cable with a measurement system.

### DETAILED DESCRIPTION

Multi-core cables are commonly used for signal and energy transmission in electronic and electrical systems. Such a cable often comprises a plurality of cores which are insulated from each other, are spatially bundled and are enclosed by a common sheath. For signal transmission, the cores are used to transmit data and information between different components. For energy transmission, the multi-core cables can be used to transmit electrical energy from a power source to a load, such as a sensor or motor or comparable electrical device.

Since multi-core cables play an important role in signal and energy transmission, it is often necessary to be able to verify whether the cable is of the desired quality.

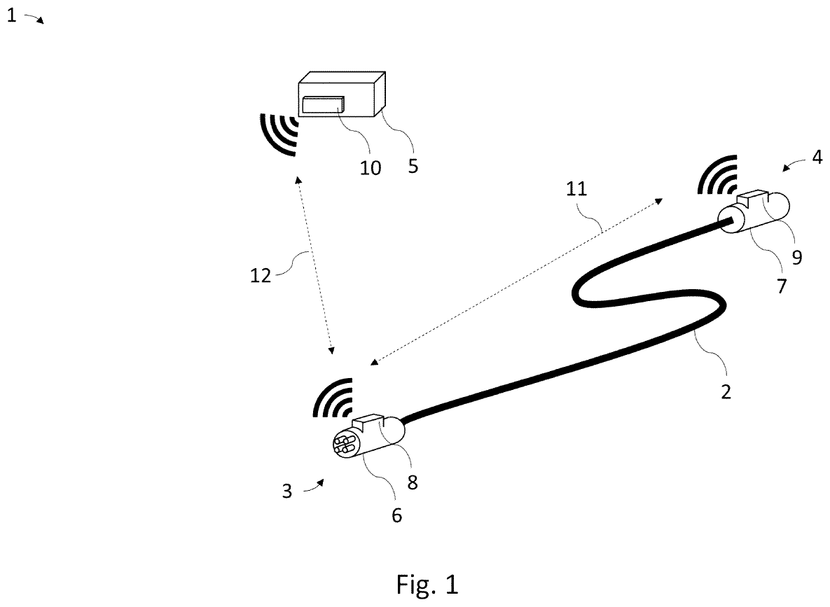

FIG. 1 shows a measurement system 1 which is used to characterize a cable 2 with a total of four cores and for this purpose has two data capture units 3 and 4 and a central processing unit 5.

The data capture units 3 and 4 are integrated in the terminals 6 and 7 which are connected to the cable 2 at the end sides. Terminal 6 is designed here as a plug with outwardly projecting contact elements, while terminal 7 is designed as a socket in a manner not shown in any more detail.

The data capture units 3 and 4 are used to each capture an electrical measurement variable at the end-side terminals 6 and 7 respectively in the active state of the cable 2. In the exemplary embodiment shown in FIG. 1, the active state denotes a state in which an electrical voltage is applied between one of the cores and the reference potential core of the cable 2. The voltage can be used here to supply voltage to a component that is contact-connected by means of the cable 2 or may be, for example, an electrical signal for controlling said component.

The data capture units 3 and 4 are designed to each measure an electrical measurement variable between one of the cores and the reference potential core. Specifically, the data capture unit 3 is used to measure a first voltage at the terminal 6 and the respective other data capture unit 4 is used to measure a second voltage at the terminal 7. If it is determined by means of the data capture units 3 and 4 that the first and second voltages between the terminals 6 and 7 differ from each other in terms of absolute value, it can be concluded, for example, that an ohmic resistance in the cable 2 is excessively high. The voltages at the terminals can be measured here at an adjustable sampling rate over a likewise adjustable period of time, in particular in order to be able to permanently monitor the active state of the cable 2.

A special feature of the measurement system 1 shown in FIG. 1 is that the communication modules 8 and 9, which are assigned to the data capture units 3 and 4, are provided for the purpose of establishing a peripheral wireless connection 11 (also: peripheral connection) between the data capture units 3 and 4, while the communication module 8 or 9 of one of the data capture units 3 or 4 is simultaneously used to establish only a single, central wireless connection 12 (also: central connection) to the central processing unit 10.

Only one central connection 12 is therefore provided between the central processing unit 5 and one of the data capture units 3 or 4 at a time during operation of the measurement system 1. This allows optimum use of all available connection points of the central processing unit 5. In particular, according to the measurement system 1 shown in FIG. 1, two central connections are not simultaneously established between the central processing unit 5 and one of the two data capture units 3 and 4 in each case, as would normally be provided in comparable wireless communication networks. Therefore, the number of required central processing units 5 can be reduced with the same number of data capture units 3, 4 or the number of usable data capture units 3, 4 can be increased when only one central processing unit 5 is used.

The communication modules 8, 9 and 10 are Bluetooth low-energy modules in the exemplary embodiment shown in accordance with FIG. 1. They communicate with each other via a Bluetooth low-energy protocol. This is a variant of the Bluetooth protocol that allows the energy requirement of the data capture units to be minimized. This is achieved, among other things, by small data packets and a fast connection establishment between the communication modules 8, 9, 10.

In a manner not shown in any more detail here, the data capture units 3, 4 each have a memory module, each of which stores an identification code in the form of a media access control (MAC) ID assigned to the respective other data capture unit 3, 4. This makes it possible for the data capture units 3, 4 to identify each other as a communication partner during an advertising process and to establish the peripheral connection 11.

After establishing the peripheral connection 11, the two data capture units 3 and 4 exchange a token until the central processing unit 5 has established the wireless central connection 12 to one of the data capture units 3, 4. The token is a character string that is stored by that data capture unit to which the central processing unit 5 is intended to establish the central connection 12. This ensures that both data capture units 3, 4 do not simultaneously establish a central connection 12 to the central processing unit 5.

If the central connection 12 is lost, the respective other data capture unit 3, 4 receives the token and the central processing unit 5 establishes the wireless central connection 12 to this data capture unit 3, 4. In this case, the data capture units each take into account a time window, within which the central connection 12 must be established before the respective other data capture unit 3, 4 receives the token back again and the central processing unit 5 attempts to establish the central connection 12 to this data capture unit 3, 4.

The data capture units 3, 4 each have an evaluation module (not shown) which is respectively configured to process the measurement variables captured at the two end-side terminals 6, 7, that is to say the electrical voltages, and to determine a variable dependent thereon, so that this can be transferred to the central processing unit 5. The dependent variable is a difference between the voltages at the terminals 6, 7. This makes it possible, together with the associated current intensity measured for the relevant core, to infer the electrical resistance of the correspondingly contact-connected core.

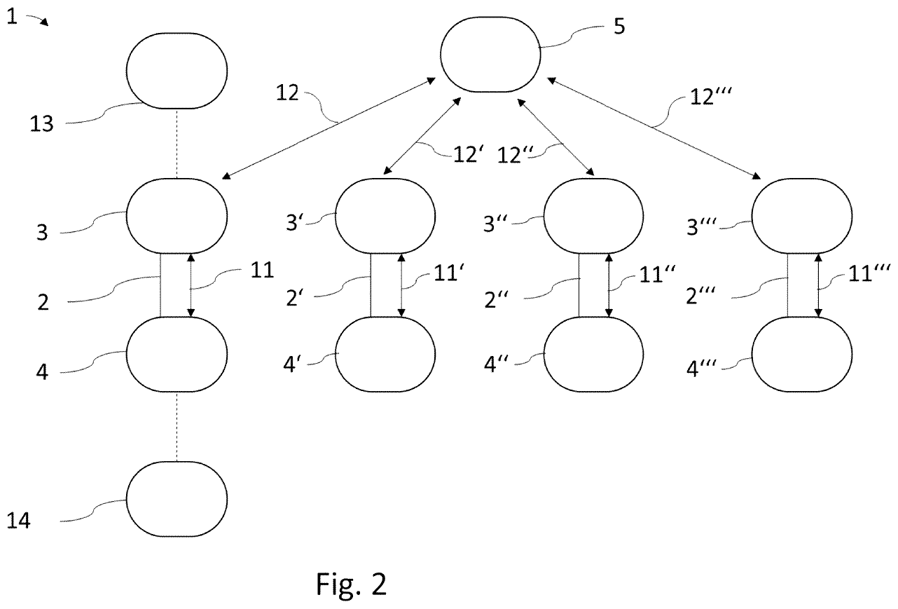

FIG. 2 shows a connection configuration of a measurement system 1 which is designed according to the embodiment shown in FIG. 1, with the result that identical reference signs are accordingly used for identical features. Two data capture units 3, 4 are thus connected to each other via a multi-core cable 2. As also explained in connection with FIG. 1, the data capture units 3, 4 are integrated in the end-side terminals of the cable 2, by means of which two electrical components 13 and 14 are connected to each other. In the case shown here, component 13 is an electrical controller and component 14 is a sensor that is controlled by means of the electrical controller and simultaneously supplies it with electrical energy. As can be seen from FIG. 2, the data capture units 3 and 4 are wirelessly connected to each other via the peripheral connection 11. At the same time, the data capture unit 3 is wirelessly connected to the central processing unit 5 via a single central connection 12.

As can also be seen from FIG. 2, a plurality of multi-core lines 2′, 2″, 2″′ etc. are each monitored by means of a pair of data capture units 3′, 4′ and 3″,4″ and 3″′,4″′ respectively. In this case, the wireless peripheral connections 11′, 11″, 11″′ are used to transmit the respectively captured measurement variables between the data capture units 3′, 4′ and 3″,4″ and 3″′, 4″′ respectively. The central connections 12′, 12″, 12″′ each exist between one of the data capture units 3′, 3″, 3″′ and the common central processing unit 5. As described above, it is advantageous that the number of central connections 12, 12′, 12″, 12″′ is higher than would be possible with conventional connection configurations.

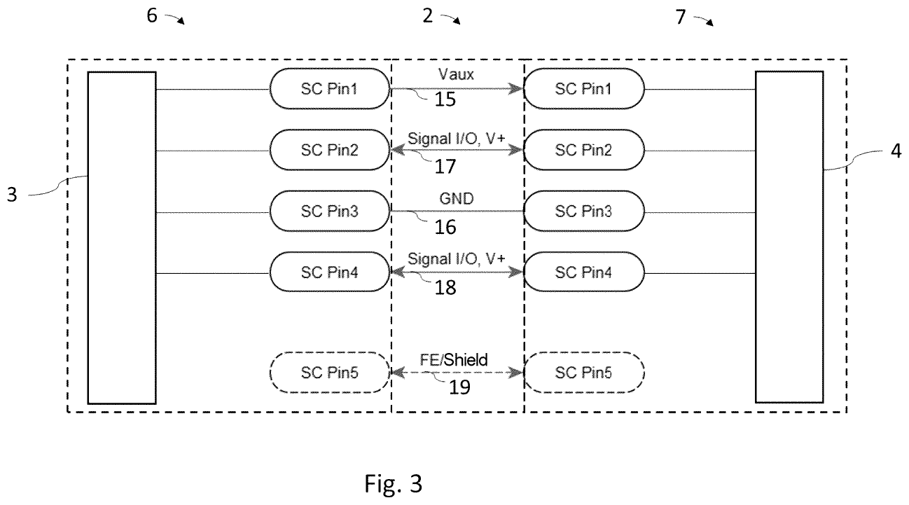

FIG. 3 shows a schematic pin assignment plan of the end-side terminals 6, 7, which are each connected to the cores 15, 16, 17 and 18 of the line 2 and in which the data capture units 3, 4 are integrated.

The terminals 6 and 7 each have five identically named pins “SC Pin1”, “SC Pin2”, “SC Pin3”, “SC Pin4” and “SC Pin5” which are assigned to each other. The cable 2 has four cores 15, 16, 17 and 18 which are electrically connected to each other via the pins “SC Pin1”, “SC Pin2”, “SC Pin3”, “SC Pin4” of the terminals 6 and 7.

Core 15 is a supply core, core 16 is a reference potential core, and cores 17 and 18 are each signal cores. The cable also comprises a shield 19 which is also electrically contact-connected via the terminals 6 and 7 and is used to shield the electrical signals within the cable from external interfering influences and at the same time prevent other devices or systems from being affected by the active state of the cable 2.

It can be seen from FIG. 3 that the data capture devices 3, 4 are contact-connected to the cores 15, 16, 17 and 18 and are used in the manner already described above to determine an electrical property of the cable 2 between the cores 15, 16, 17 and 18 based on the electrical voltages and on the electrical current of the respective core. As already described in connection with FIG. 1, a conclusion on the ohmic resistance of at least one of the cores 15, 16, 17, 18 can be drawn by forming a difference between the measured voltages at the terminals 6 and 7 and measuring the applied current.

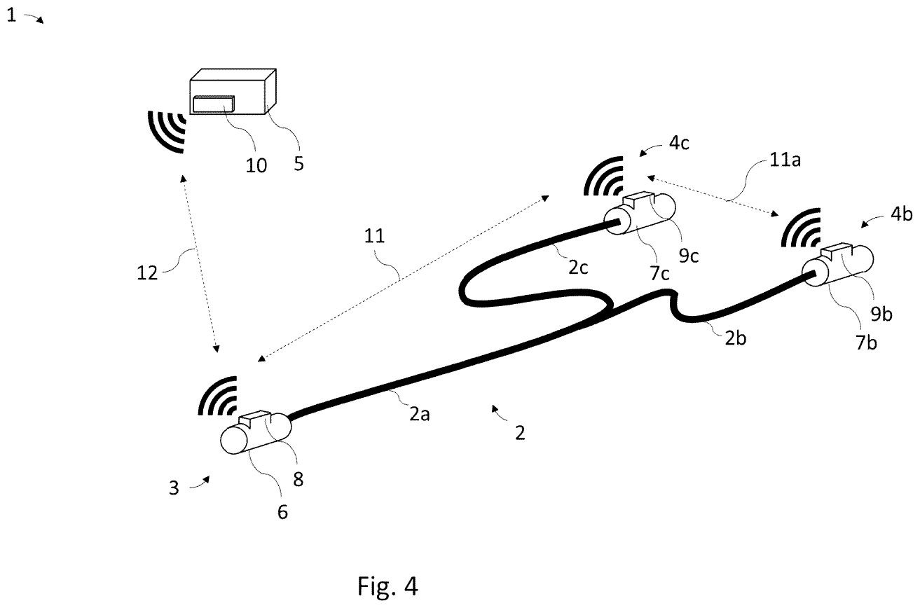

FIG. 4 shows another exemplary embodiment of a measurement system 1 which has a total of three data capture units 3, 4b, 4c and the central processing unit 5. The data capture units 3, 4b, 4c are each integrated in the end-side terminals 6 and 7b and 7c of a Y-cable and are used to characterize the latter. The Y-cable has, in a manner known per se, a trunk section 2a and two branch sections 2b, 2c. According to the statements in connection with FIG. 3, the trunk section has a total of four cores and a shield, which are each divided among the branch sections 2b, 2c. In other words, the branch sections 2b and 2c also respectively have four cores and a shield, which are connected to the four cores and the shield of the trunk section 2a.

The data capture units 3, 4b, 4c are each used to capture an electrical voltage at the end-side terminals 6, 7b, 7c in an active state of the Y-cable. The data capture units 3, 4b, 4c each comprise in this case, according to the statements made with respect to FIG. 1, a communication module 8, 9b, 9c. The communication modules 8, 9b, 9c are provided for establishing two wireless peripheral connections 11 and 11a between the data capture units 3, 4b, 4c, wherein the peripheral connection 11 exists between the data capture units 3 and 4c and the peripheral connection 11a exists between the data capture units 4b and 4c. Alternatively, the peripheral connection 11a may also exist between the data capture units 3 and 4b. The communication module 8 of the data capture unit 3 is also designed to establish a single wireless central connection 12 to the communication module 10 of the central processing unit 5.

It is an advantage that, even for the characterization of the Y-cable, only one central connection 12 is required between one of the three data capture units 3, 4b, 4c and the central processing unit 5. According to the connection configuration shown in FIG. 5, the data capture unit 3 is connected to the central processing unit 5 via the single central connection 12 and is simultaneously connected to one of the data capture units 4c via the peripheral connection 11. Alternatively, the data capture unit 3 could also be connected to the central processing unit 5 via the central connection 12 and could be simultaneously connected to the data capture units 4b and 4c via two peripheral connections.

1. A measurement system (1) for characterizing a multi-core cable (2), the measurement system comprising:
at least two data capture units (3, 4, 4b, 4c);
a central processing unit (5);
wherein the two data capture units (3, 4, 4b, 4c) are each provided for being contact-connected to the cable (2) at an end-side terminal (6, 7, 7b, 7c) and are configured to each capture an electrical measurement variable at the end-side terminals (6, 7, 7b, 7c) at least in an active state of the cable (2);
the data capture units (3, 4, 4b, 4c) and the central processing unit (5) each comprise a communication module (8, 9, 10);
the communication modules (8, 9, 9b, 9c) of the data capture units (3, 4, 4b, 4c) are configured for establishing a wireless peripheral connection (11) between the data capture units (3, 4, 4b, 4c) in order to transfer the respectively captured measurement variable from one of the data capture units (3, 4, 4b, 4c) to the respective other data capture unit (3, 4, 4b, 4c); and
the communication module (8, 9, 9b, 9c) of at least one of the data capture units (3, 4, 4b, 4c) and the communication module (10) of the central processing unit (5) are configured for establishing a single wireless central connection (12) between the at least one of the two data capture units (3, 4, 4b, 4c) and the central processing unit (5) in order to transfer at least one of the captured measurement variables and/or a variable dependent thereon to the central processing unit (5).

2. The measurement system (1) according to claim 1, wherein
the communication modules (8, 9, 9b, 9c, 10) of the data capture units (3, 4, 4b, 4c) and of the central processing unit (5) are each Bluetooth modules.

3. The measurement system (1) according to claim 1, wherein
the data capture units (3, 4, 4b, 4c) are each integrated in one of the end-side terminals (6, 7, 7b, 7c) and the end-side terminals (6, 7, 7b, 7c) are provided for being connected to at least two cores of the cable (2).

4. The measurement system according to claim 3, wherein
one of the end-side terminals (3, 4, 4b, 4c) comprises a plug and the respective other of the end-side terminals comprises a socket.

5. The measurement system (1) according to claim 3, wherein
the data capture units (3, 4, 4b, 4c) are each configured to be electrically contact-connected to at least one of a supply core (15) or a signal core (17, 18) and a reference potential core (16) of the cable (2), and to measure at least one of a) a current intensity in the at least one of the supply core (15) or the signal core (17, 18) and/or the reference potential core (16), or b) a voltage between the at least one of supply core (15) or the signal core (17, 18) and the reference potential core (16).

6. The measurement system (1) according to claim 3, wherein
the data capture units (3, 4, 4b, 4c) are each configured to be electrically contact-connected to a signal core (17, 18) and to capture a signal characteristic in the signal core (17, 18).

7. The measurement system (1) according to claim 1, wherein
at least one of a) the data capture units (3, 4, 4b, 4c) or b) the central processing unit (5) each have a memory module on which an identification code is stored, via which at least one of a) the data capture units are assigned to each other for the wireless peripheral connection (11) or b) at least one of the data capture units (3, 4, 4b, 4c) is assigned to the central processing unit (5) for the wireless central connection (12).

8. The measurement system (1) according to claim 1, wherein
at least one of the data capture units (3, 4, 4b, 4c), which is configured to communicate with the central processing unit (5), has an evaluation module which is configured to process the measurement variables captured at the two end-side terminals (3, 4, 4b, 4c) and to transfer a variable dependent thereon to the central processing unit (5).

9. The measurement system (1) according to claim 8, wherein
the variable dependent on the measurement variables comprises at least one of a difference or a quotient between the measured measurement variables at the end-side terminals (3, 4, 4b, 4c).

10. The measurement system (1) according to claim 8, wherein
the variable dependent on the measurement variables comprises a temporal profile of at least one of the measurement variables.

11. The measurement system (1) according to claim 8, wherein
the variable dependent on the measurement variables comprises at least one of a cable impedance or a signal propagation time in the active state of the cable.

12. The measurement system (1) according to claim 1, wherein the multi-core cable (2) comprise a multi-core Y-cable (2), and the at least two data capture units comprises at least three of the data capture units (3, 4, 4b, 4c), each provided for being contact-connected at the end-side terminals (6, 7, 7b, 7c) of the multi-core Y-cable (2), and each configured to capture an electrical measurement variable at one of the end-side terminals (6, 7b, 7c) at least in the active state of the Y-cable (2),
the data capture units (3, 4, 4b, 4c) each comprise one of the communication modules (8, 9b, 9c), wherein the communication modules (8, 9b, 9c) are each provided for establishing two wireless peripheral connections (11, 11a) between two of the three data capture units (3, 4, 4b, 4c) in each case, and
the communication module (8, 9, 9b, 9c) of one of the data capture units (3, 4b, 4c) is also designed to establish the only wireless central connection (12) to the communication module (10) of the central processing unit (5) in order to transfer at least one of the captured measurement variables to the central processing unit (5).

13. A method for characterizing a multi-core cable (2), comprising the steps of:
A) providing a measurement system (1) according to claim 1;
B) electrically contact-connecting at least two of the data capture units (3, 4, 4b, 4c) to the cable (2) via the end-side terminals (6, 7, 7b, 7c) in each case;
C) applying an electrical voltage to the cable (2);
D) establishing the wireless peripheral connection (11, 11a) between the data capture units (3, 4, 4b, 4c) of the measurement system;
E) establishing the single wireless central connection (12) between the central processing unit (5) and one of the two data capture units (3, 4, 4b, 4c);
F) capturing the at least two electrical measurement variables at the terminals (6, 7, 7b, 7c);
G) transferring at least one of the captured measurement variables between the data capture units (3, 4, 4b, 4c); and
H) transmitting at least one of the captured measurement variables and/or a variable dependent thereon from only one of the data capture units (3, 4, 4b, 4c) to the central processing unit (5).

14. The method according to claim 13, wherein method step D) comprises advertising between the communication modules (8, 9, 9b, 9c) of the data capture units (3, 4, 4b, 4c).

15. The method according to claim 14, wherein according to method step D), one of the at least two data capture units (3, 4, 4b, 4c) provides the respective other of the two data capture units (3, 4, 4b, 4c) with an advertising time window and, if the central connection (12) is lost and the advertising time window is exceeded, the central processing unit (5) establishes a wireless central connection (12) to the respective other data capture unit (3, 4, 4b, 4c).

16. The method according to claim 13, wherein before method step E), the at least two data capture units (3, 4, 4b, 4c) exchange a token until the central processing unit (5) has established the central connection (12) to one of the data capture units (3, 4, 4b, 4c).

17. The method according to claim 13, wherein before method step E), advertising takes place between at least one of the communication modules of the data capture units (3, 4, 4b, 4c) and the communication module of the central processing unit.

18. The method according to claim 17, further comprising assigning, via the central processing unit, a Received Signal Strength Indicator (RSSI) value is assigned to at least one of the two data capture units (3, 4, 4b, 4c) and storing the RSSI value.

19. The method at least according to claim 17, further comprising assigning, via the central processing unit, a Received Signal Strength Indicator (RSSI) value respectively to the two data capture units (3, 4, 4b, 4c) and storing the RSSI value, and the central connection (12) is established between the central processing unit (5) and that data capture unit (3, 4, 4b, 4c) to which a higher of the RSSI values is assigned.
